(19) United States
(12) Patent Application Publication
(10) Pub. No.: US 2026/0223727 A1
(43) Pub. Date: Jul. 30, 2026

(54) HOUSING, ELECTRONIC DEVICE HAVING THE HOUSING, AND MANUFACTURING METHOD THEREOF

(71) Applicant: Advanced Semiconductor Engineering, Inc., Kaohsiung (TW)

(72) Inventors: Chung Ju YU, Kaohsiung (TW); Cheng Yi HUANG, Kaohsiung (TW)

(73) Assignee: Advanced Semiconductor Engineering, Inc., Kaohsiung (TW)

(21) Appl. No.: 19/037,017

(22) Filed: Jan. 24, 2025

(51) Int. Cl. H01L 23/053; H01L 21/48; H01L 21/52; H01L 23/00; H01L 23/10; H01L 23/24; H01L 23/31; H01L 23/538; H01L 25/065

(52) U.S. Cl. CPC H10W 76/15; H10W 72/071; H10W 74/114; H10W 76/47; H10W 76/60; H10W 99/00; H10W 70/65; H10W 90/00; H10W 90/754

(57) ABSTRACT

The present disclosure provides an electronic device. The electronic device includes a carrier, a housing disposed over the carrier and having a holder, and an interconnection structure disposed in the holder and electrically connected with the carrier. The holder extends continuously between a top surface and a bottom surface of the housing. The housing and the interconnection structure are detachable from the carrier. The present disclosure also provides a housing and a method for manufacturing an electronic device.

### BACKGROUND

### 1. Technical Field

The present disclosure relates to a housing, an electronic device having the housing, and a method for manufacturing an electronic device.

### 2. Description of the Related Art

In power module manufacturing, the housing is initially placed on the substrate to shield the electronic components. Subsequently, pins are inserted into the housing to establish electrical connections with slots on the substrate. Proper space allocation for the slots is crucial to prevent electrical issues. This process is complex and increases the cost of the housing.

### SUMMARY

In some arrangements, an electronic device includes a carrier, a housing disposed over the carrier and having a holder, and an interconnection structure disposed in the holder and electrically connected with the carrier. The holder extends continuously between a top surface and a bottom surface of the housing. The housing and the interconnection structure are detachable from the carrier.

In some arrangements, an electronic device includes a cover, a sidewall extending from the cover and having a first bottom surface, and a holder extending from the cover and having a second bottom surface. The electronic device also includes an interconnection structure secured in the holder. The first bottom surface is substantially aligned with the second bottom surface.

In some arrangements, a method for manufacturing an electronic device includes providing a housing including a holder; disposing an interconnection structure in the holder; and disposing the housing, along with the interconnection structure, over a carrier.

### BRIEF DESCRIPTION OF THE DRAWINGS

Aspects of some arrangements of the present disclosure are best understood from the following detailed description when read with the accompanying figures. It is noted that various structures may not be drawn to scale, and dimensions of the various structures may be arbitrarily increased or reduced for clarity of discussion.

FIG. 1A illustrates a cross-sectional view of an electronic device in accordance with some arrangements of the present disclosure.

FIG. 1B illustrates a cross-sectional view of a portion of an electronic device in accordance with some arrangements of the present disclosure.

FIG. 1C illustrates a cross-sectional view of a portion of an electronic device in accordance with some arrangements of the present disclosure.

FIG. 1D illustrates a cross-sectional view of a portion of an electronic device in accordance with some arrangements of the present disclosure.

FIG. 1E illustrates a perspective view of a housing in accordance with some arrangements of the present disclosure.

FIG. 1F illustrates a perspective view of a housing in accordance with some arrangements of the present disclosure.

FIG. 2A illustrates a cross-sectional view of an electronic device in accordance with some arrangements of the present disclosure.

FIG. 2B illustrates a cross-sectional view of an electronic device in accordance with some arrangements of the present disclosure.

FIG. 2C illustrates a perspective view of a housing in accordance with some arrangements of the present disclosure.

FIG. 2D illustrates a perspective view of a housing in accordance with some arrangements of the present disclosure.

FIG. 3A, FIG. 3B, FIG. 3C, FIG. 3D, FIG. 4A, and FIG. 4B illustrate cross-sectional views in one or more stages of a method of manufacturing an electronic device in accordance with an arrangement of the present disclosure.

### DETAILED DESCRIPTION

Common reference numerals are used throughout the drawings and the detailed description to indicate the same or similar components. Arrangements of the present disclosure will be readily understood from the following detailed description taken in conjunction with the accompanying drawings.

The following disclosure provides many different arrangements, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include arrangements in which the first and second features are formed or disposed in direct contact, and may also include arrangements in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various arrangements and/or configurations discussed.

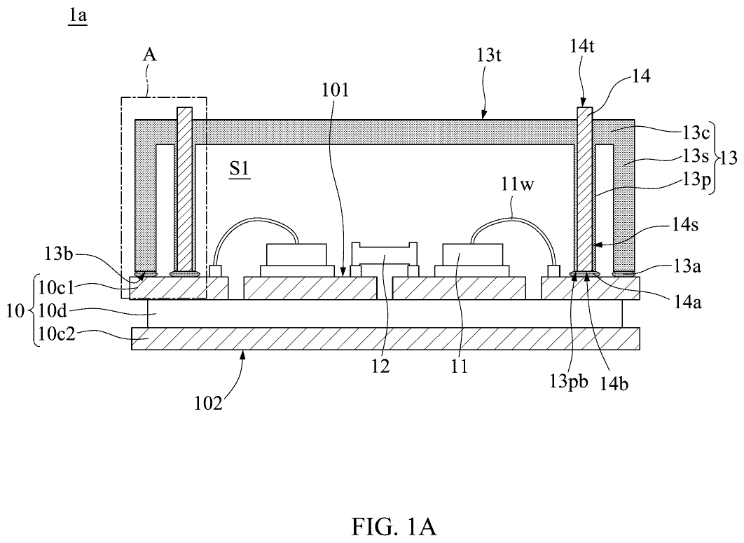

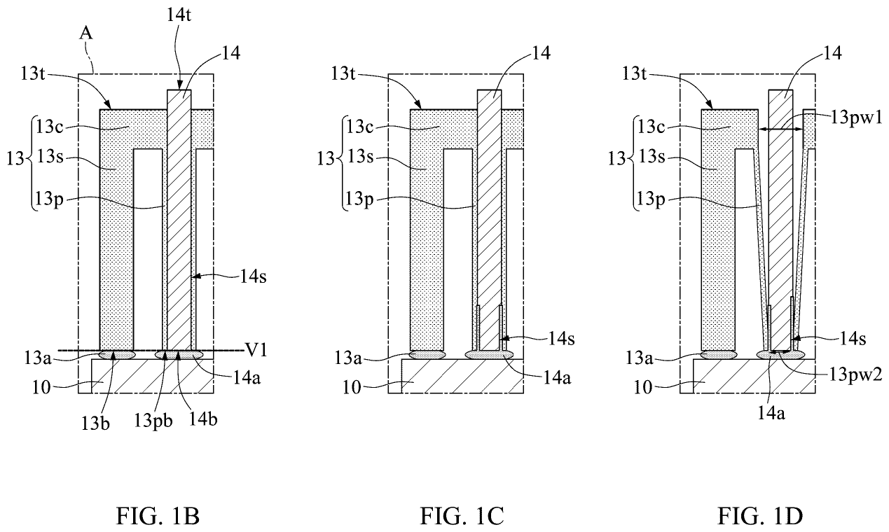

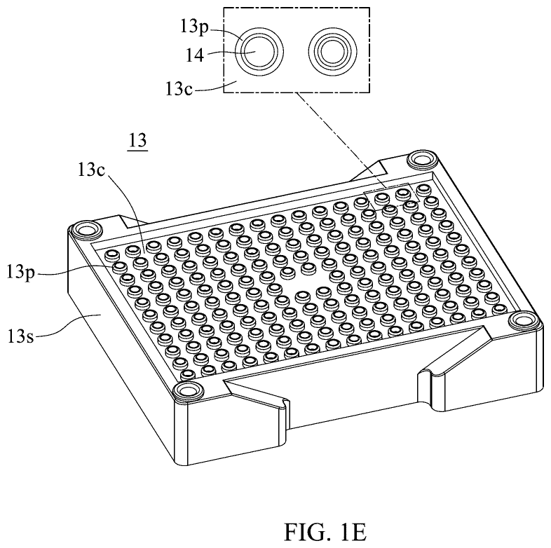

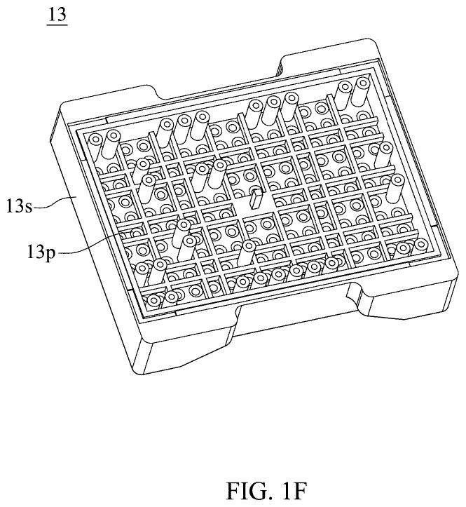

FIG. 1A illustrates a cross-sectional view of an electronic device 1a in accordance with some arrangements of the present disclosure. In some arrangements, the electronic device 1a may include a package, such as a semiconductor device package. In some arrangements, the electronic device 1a may include a carrier 10, electronic components 11 and 12, a housing 13, and interconnection structures 14.

The carrier 10 may include a supporting layer for structurally supporting the electronic components 11 and 12, the housing 13, and the interconnection structures 14. In some arrangements, the carrier 10 may include a substrate fabricated from materials such as silicon, glass, ceramics, polyimide, or semiconductors like gallium arsenide (GaAs), indium phosphide (InP), silicon carbide (SiC), and gallium nitride (GaN). In some arrangements, the carrier 10 may include, for example, a printed circuit board (PCB), such as a paper-based copper foil laminate, a composite copper foil laminate, or a polymer-impregnated glass-fiber-based copper foil laminate. In some arrangements, the carrier 10 may include a core layer 10d and conductive layers 10c1 and 10c2 disposed on opposite surfaces of the core layer 10d.

The carrier 10 may include a surface 101 and a surface 102 opposite to the surface 101. The carrier 10 may include one or more conductive pads (not shown) in proximity to, adjacent to, or embedded in and exposed from the surface 101 and/or 102 of the carrier 10. The carrier 10 may include a solder resist (not shown) on the surface 101 and/or 102 of the carrier 10 to fully expose or to expose at least a portion of the conductive pads for electrical connections, including, for example, the power routing path (or the power path) and the signal routing path (or the signal path) in the electronic device 1a.

The term “power path,” as used and described herein, refers to a path specifically designated for power supply connections. The term “signal path,” as used and described herein, denotes a route through which electrical signals are transmitted. These electrical signals may include either analog or digital signals.

In some arrangements, the carrier 10 may provide power and/or ground connections to the devices or components electrically connected with the carrier 10. For example, the carrier 10 may have a connector or terminal configured to be electrically connected with a power source or a power supply (not illustrated in the figures). The carrier 10 may provide a power path between the power supply and a power regulating device, which in turn may provide regulated power to an active device electrically connected with the carrier 10.

The electronic components 11 and 12 may be disposed over or on the surface 101 of the carrier 10. In some arrangements, the electronic components 11 and 12 may each be electrically connected to one or more other devices (if any) and to the carrier 10, and the electrical connection may be attained by way of flip-chip, wire-bond techniques, metal-to-metal bonding (such as Cu to Cu bonding), or hybrid bonding. For example, the electronic component 11 may be electrically connected to the carrier 10 by a conductive wire 11w.

In some arrangements, the electronic component 11 may include an active device or an active component. The electronic component 11 may be or include circuits or circuit elements that rely on an external power supply to control or modify electrical signals. For example, the electronic component 11 may include a central processing unit (CPU), a microprocessor unit (MPU), a graphics processing unit (GPU), a microcontroller unit (MCU), an application-specific integrated circuit (ASIC), a field-programmable gate array (FPGA), or another type of integrated circuit.

In some arrangements, the electronic component 11 may include a power management integrated circuit (PMIC). For example, the electronic component 11 may be configured to receive power from a power source or a power supply (not illustrated in the figures), and provide regulated power to an active device (not illustrated in the figures) electrically connected with the carrier 10. For example, the electronic component 11 may be configured to provide power control to an active device electrically connected with the carrier 10.

In some arrangements, the electronic component 12 may include a passive device or a passive component, such as resistors, capacitors, inductors, or a combination thereof. The electronic component 11 and the electronic component 12 may include different functions. For example, the electronic component 11 may include an active device and the electronic component 12 may include a passive device.

The positions, functions, and numbers of the electronic components in the electronic device 1a are not intended to limit the present disclosure. For example, there may be any number of electronic components in the electronic device 1a due to design requirements.

The housing 13 may be disposed over or on the surface 101 of the carrier 10. The housing 13 may cover, protect, or shield the electronic component 11 and the electronic component 12.

The housing 13 may include a cover 13c and a sidewall 13s. The cover 13c may be or include a substantially flat or planar lid. The cover 13c may have a top surface 13t, which may be the highest surface of the housing 13. The sidewall 13s may extend downward from an edge of the cover 13c. The sidewall 13s may enclose or surround the electronic component 11 and the electronic component 12. The sidewall 13s may support the cover 13c over the carrier 10. The sidewall 13s may have a bottom surface 13b. The bottom surface 13b may be the lowest surface of the housing 13. The sidewall 13s may extend between the top surface 13t and the bottom surface 13b. For example, the sidewall 13s may extend continuously between the top surface 13t and the bottom surface 13b.

The housing 13 may include a holder 13p. The holder 13p may include a wall or a partition extending downward from the cover 13c. The holder 13p may be or include a hollow structure. The holder 13p may be or include a hollow cylinder or a hollow cylindrical body. The holder 13p may define an opening or a hole configured to receive the interconnection structure 14. In some arrangements where the interconnection structure 14 is a pin, the holder 13p may be referred to as a pin holder.

The holder 13p may have a bottom surface 13pb. The bottom surface 13pb may be the lowest surface of the housing 13. The holder 13p may extend continuously between the top surface 13t and the bottom surface 13b. The holder 13p may be disposed on the inside with respective to the sidewall 13s. The holder 13p and the sidewall 13s may have substantially the same height or length.

In some arrangements, the bottom surface 13pb of the holder 13p and the bottom surface 13b of the sidewall 13s may be the lowest surface of the housing 13. In some arrangements, the bottom surface 13pb of the holder 13p and the bottom surface 13b of the sidewall 13s may be substantially aligned. In some arrangements, the bottom surface 13pb of the holder 13p and the bottom surface 13b of the sidewall 13s may be substantially at the same elevation with respect to the surface 101 of the carrier 10. In some arrangements, the bottom surface 13pb of the holder 13p and the bottom surface 13b of the sidewall 13s may be referred to as a first bottom surface and a second bottom surface, or vice versa.

The housing 13 may be a monolithic structure. For example, the housing 13 may be constructed as a single, unified piece. For example, the holder 13p, the sidewall 13s, and the cover 13c may be seamlessly integrated into one continuous structure.

In some arrangements, the housing 13 may include insulation or dielectric material. In some arrangements, the housing 13 may include an epoxy resin having fillers, a molding compound (e.g., an epoxy molding compound or other molding compound), a polyimide, a thermoplastic polyurethane (TPU), soda-lime-silica glass, alkali-aluminosilicate glass, liquid silicone rubber (LSR), polycarbonate (PC), nylon, polybutylene terephthalate (PBT), a phenolic compound or material, a material with a silicone dispersed therein, or a combination thereof.

In some arrangements, the housing 13 may be connected with the carrier 10 through a contact 13a. The contact 13a may include a connection or a connecting element. In some arrangements, the contact 13a may include a combination of materials such as glue, adhesive, or other bonding agents to ensure a secure and reliable connection.

The interconnection structure 14 may be disposed over or on the surface 101 of the carrier 10. The interconnection structure 14 may be received or accommodated in the holder 13p. The holder 13p may surround a lateral surface 14s of the interconnection structure 14. The diameter of the opening defined by the holder 13p may be greater than the diameter of the interconnection structure 14. The diameter of the interconnection structure 14 may be smaller than the diameter of the opening defined by the holder 13p.

The interconnection structure 14 may be secured or fixed in the holder 13p. The interconnection structure 14 may be attached to the holder 13p through a mechanical or magnetic means. The mechanical or magnetic means may prevent unintended separation of the interconnection structure 14 and the holder 13p. The mechanical or magnetic means may include locking elements, fastening elements, retaining elements, etc. More specifically, the mechanical or magnetic means may include a pin, a post, a spring, a plugger, a buffer, a snap, a clip, a contour, etc.

In some arrangements, the interconnection structure 14 may include a conductive pin. However, the disclosure is not limited thereto. In some arrangements, the interconnection structure 14 may include a conductive via, a conductive wire, a conductive pillar, or other conductive elements.

In some arrangements, the interconnection structure 14 may protrude beyond the top surface 13t of the housing 13. For example, the interconnection structure 14 may extend from the top surface 13t into the holder 13p. For example, the interconnection structure 14 may have an elongation direction, an extending direction, or a longer side in a direction from the top surface 13t into the holder 13p.

The housing 13 and the carrier 10 may together define or enclose a space S1. The space S1 may be an air space. In some arrangements, the interconnection structure 14 may be separated from the space S1 by the holder 13p. For example, the interconnection structure 14 may be covered or surrounded by the holder 13p. For example, the interconnection structure 14 may not be exposed to the space S1.

In some arrangements, the interconnection structure 14 may be overlapped with the holder 13p horizontally (e.g., in a direction substantially parallel with the surface 101 and/or the surface 102 of the carrier 10). For example, the holder 13p may be entirely overlapped with the lateral surface 14s of the interconnection structure 14 horizontally. For example, the lateral surface 14s of the interconnection structure 14 in the space S1 may be entirely overlapped with the holder 13p horizontally.

In some arrangements, the interconnection structure 14 may include, for example, gold (Au), silver (Ag), copper (Cu), nickel (Ni), palladium (Pd), another metal(s) or alloy(s), or a combination of two or more thereof.

In some arrangements, the interconnection structure 14 may be electrically connected with the carrier 10 through an electrical contact 14a. In some arrangements, the electrical contact 14a may include a combination of materials such as glue, adhesive, or other bonding agents to ensure a secure and reliable connection. In some arrangements, the electrical contact 14a may include a flowable conductive material. In some arrangements, the electrical contact 14a may include a soldering material. In some arrangements, the electrical contact 14a may include, for example, eutectic Sn/Pb, high-lead solder, lead-free solder, pure tin solder, or other types of solders.

In some arrangements, the electrical contact 14a may be disposed between the interconnection structure 14 and the carrier 10. The electrical contact 14a may be disposed between the holder 13p and the carrier 10. The contact 13a may be disposed between the sidewall 13s and the carrier 10.

In some arrangements, the electrical contact 14a and/or the contact 13a may be optional. For example, the interconnection structure 14 may contact (such as directly contact) the carrier 10. For example, the holder 13p may contact (such as directly contact) the carrier 10. For example, the sidewall 13s may contact (such as directly contact) the carrier 10.

In some arrangements, the contact 13a and the electrical contact 14a may have the same material. In some arrangements, the contact 13a and the electrical contact 14a may have different materials. For example, the electrical contact 14a may have better conductivity than the contact 13a.

In some arrangements, the interconnection structure 14 may be configured to be electrically connected with a power source or a power supply (not illustrated in the figures). In some arrangements, the interconnection structure 14 may be configured to provide, define, construct, or establish a power path for transmitting a power from a power source to a power management integrated circuit (such as the electronic component 11).

In some arrangements, the interconnection structure 14 may be configured to be electrically connected with an active device (not illustrated in the figures). In some arrangements, the interconnection structure 14 may be configured to provide, define, construct, or establish a power path for transmitting a regulated power from a power management integrated circuit (such as the electronic component 11) to an active device.

In some arrangements, the interconnection structure 14 and the housing 13 may be detachable or removable from the carrier 10. For example, the interconnection structure 14 and the housing 13 may be configured to be detached or removed from the carrier 10. For example, the interconnection structure 14 and the housing 13 may be configured to be detached from the carrier 10 for repair and maintenance. For example, the interconnection structure 14 and the housing 13 may be configured to be detached from the carrier 10 without breaking or destroying the structure or function of the carrier 10. For example, the interconnection structure 14 may be configured to be detached from the carrier 10 along with the housing 13.

In a comparative arrangement where the housing does not include a pin holder, it is essential to maintain slots on the carrier. Pins are inserted into the housing to create electrical connections with the slots on the substrate. This process is complex and contributes to the increased cost of the housing.

According to some arrangements of the present disclosure, by using the housing 13 with the holders 13p, the interconnection structures 14 can be first fixed on the housing 13 and then the housing 13 can be placed on the carrier 10, while simultaneously connecting the interconnection structures 14 to the electrical connectors of the carrier 10. With this new type of housing 13, there is no need to pre-reserve slots on the carrier 10, and the housing 13 can have many holders 13p, allowing for more flexible electrical connections. In addition, assembling the housing 13 with the carrier 10 after forming a semi-finished product can simplify the process and reduce overall material costs. Furthermore, the downward extension structures of the holders 13p serve a functional purpose by providing extra support and stability to the entire assembly. These holders 13p also help protect the electronic components 11 and 12 from external elements such as dust and moisture, while enhancing the structural integrity of the complete unit.

FIG. 1B illustrates a cross-sectional view of the area enclosed by the dashed box A in the electronic device 1a in accordance with some arrangements of the present disclosure.

The interconnection structure 14 may have end surfaces 14t and 14b opposite to each other. The lateral surface 14s of the interconnection structure 14 may extend between the end surfaces 14t and 14b.

The end surface 14b may face the carrier 10. The end surface 14b of the interconnection structure 14, the bottom surface 13pb of the holder 13p, and the bottom surface 13b of the sidewall 13s may be substantially aligned. For example, the end surface 14b of the interconnection structure 14, the bottom surface 13pb of the holder 13p, and the bottom surface 13b of the sidewall 13s may be substantially aligned along a virtual surface V1.

In some arrangements, the electrical contact 14a may be disposed between the end surface 14b of the interconnection structure 14 and the carrier 10. In some arrangements, the electrical contact 14a may be disposed between the bottom surface 13pb of the holder 13p and the carrier 10. In some arrangements, the electrical contact 14a may be disposed below the virtual surface V1.

In some arrangements, the contact 13a may be disposed between the bottom surface 13b of the sidewall 13s and the carrier 10. In some arrangements, the contact 13a may be disposed below the virtual surface V1.

FIG. 1C illustrates a cross-sectional view of the area enclosed by the dashed box A in the electronic device 1a in accordance with some arrangements of the present disclosure. FIG. 1C is similar to FIG. 1B except for the differences described as follows.

As mentioned, the electrical contact 14a may include a reflowable material or a soldering material. In some arrangements, when the reflowable temperature of the electrical contact 14a is reached, the electrical contact 14a can be softened, liquefied, or become flowable and may climb or flow onto the lateral surface 14s of the interconnection structure 14 (e.g., into the holder 13p).

In some arrangements, the electrical contact 14a may be connected with the interconnection structure 14 and the holder 13p, forming a bonding structure or a bonding element. In some arrangements, the electrical contact 14a may provide a connection (e.g., a horizontal connection) between the interconnection structure 14 and the holder 13p. In some arrangements, the electrical contact 14a may provide a connection (e.g., a vertical connection) between the interconnection structure 14 and the carrier 10.

In some arrangements, the electrical contact 14a, the interconnection structure 14, and the holder 13p may be overlapped horizontally (e.g., in a direction substantially parallel with the surface 101 and/or the surface 102 of the carrier 10 in FIG. 1A).

FIG. 1D illustrates a cross-sectional view of the area enclosed by the dashed box A in the electronic device 1a in accordance with some arrangements of the present disclosure. FIG. 1D is similar to FIG. 1B except for the differences described as follows.

The holder 13p may taper toward the carrier 10. The holder 13p may taper away from the cover 13c. For example, the sidewall of the holder 13p may have an end (which may also be referred to as a first end) proximal to (or connected to) the top surface 13t and an end (which may also be referred to as a second end) distal from the top surface 13t. In a cross-sectional view, the proximal end may define an opening (which may also be referred to as a first opening) having a width (which may also be referred to as a first width) 13pw1, and the distal end may define an opening (which may also be referred to as a second opening) having a width (which may also be referred to as a second width) 13pw2 smaller than the width 13pw1. For example, the width 13pw1 may be the greatest width or diameter of the holder 13p. For example, the width 13pw2 may be the smallest width or diameter of the holder 13p.

In some arrangements, a gap between the holder 13p and the lateral surface 14s of the interconnection structure 14 may increase or widen as it approaches or moves toward the cover 13c.

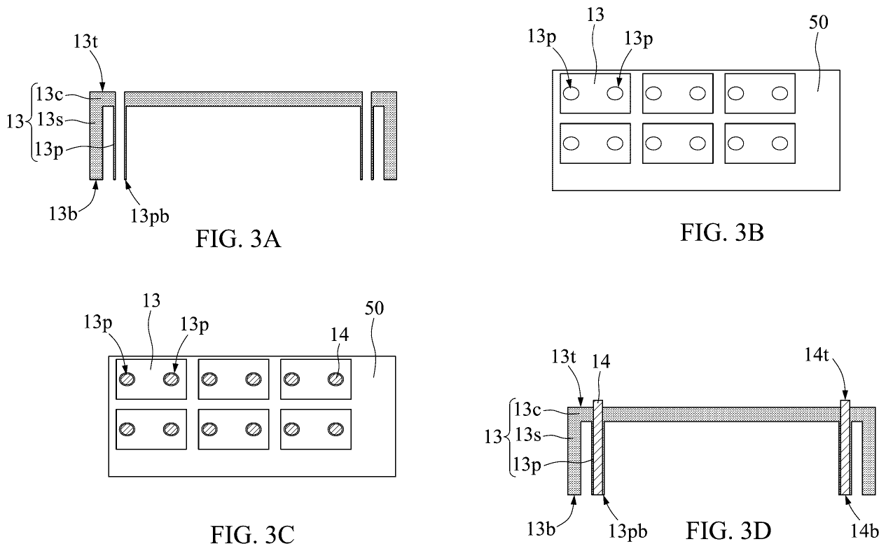

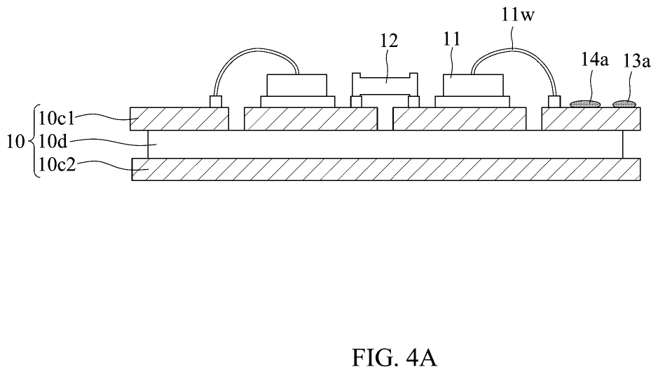

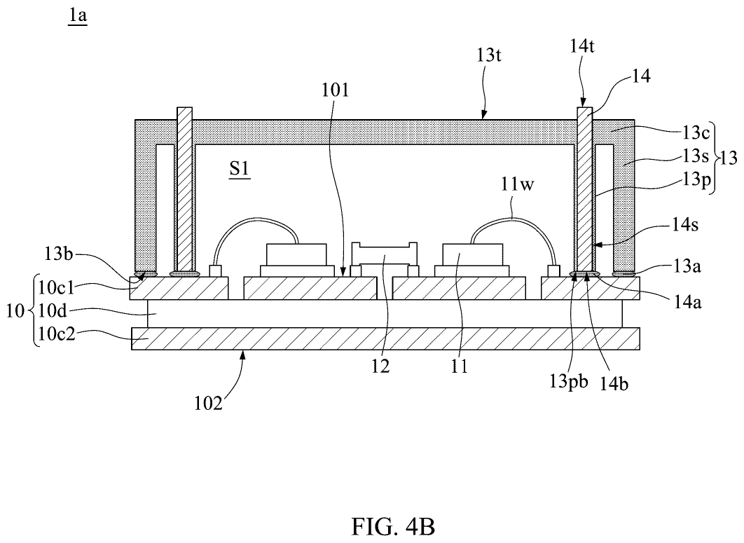

In a cross-sectional view, the interconnection structure 14 may be spaced farther from the proximal end than from the distal end. In some arrangements, the electrical contact 14a may climb or flow onto the lateral surface 14s of the distal end of the interconnection structure 14. In some arrangements, the tapered structure (or the wider gap) of the holder 13p may be beneficial to the inserting operation (as shown in FIG. 3C).

In some arrangements, the height of the electrical contact 14a climbing onto the lateral surfaces 14s of the interconnection structure 14 may differ on opposite sides.

FIG. 1E and FIG. 1F illustrate perspective views from different angles of the housing 13 in accordance with some arrangements of the present disclosure. In some arrangements, the housing 13 of the electronic device 1a in FIG. 1A may have perspective views as shown in FIG. 1E and FIG. 1F.

In some arrangements, the housing 13 may have a plurality of holders 13p. The interconnection structures 14 can be inserted or accommodated in one or more holders 13p based on specific requirements. For example, the interconnection structures 14 can be inserted or accommodated in one or more holders 13p, depending on the routing of the power paths.

The shapes, positions, relative locations, and quantities of the holders 13p are for illustrative purposes only and are not intended to limit the scope of the present disclosure.

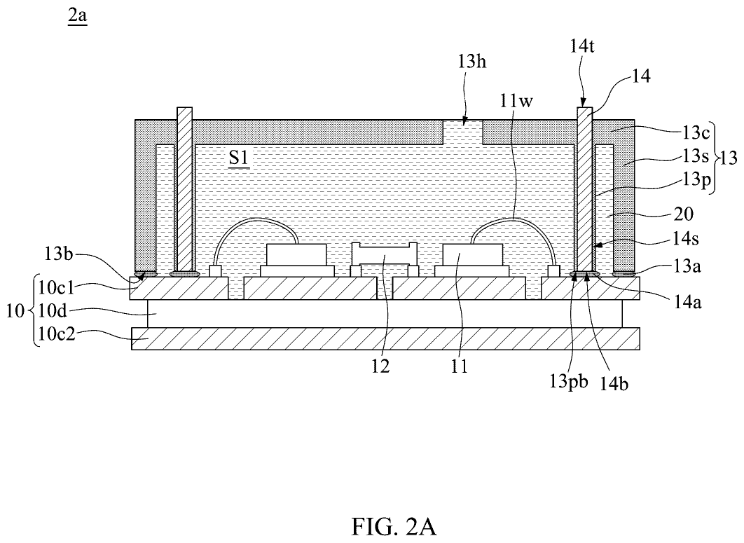

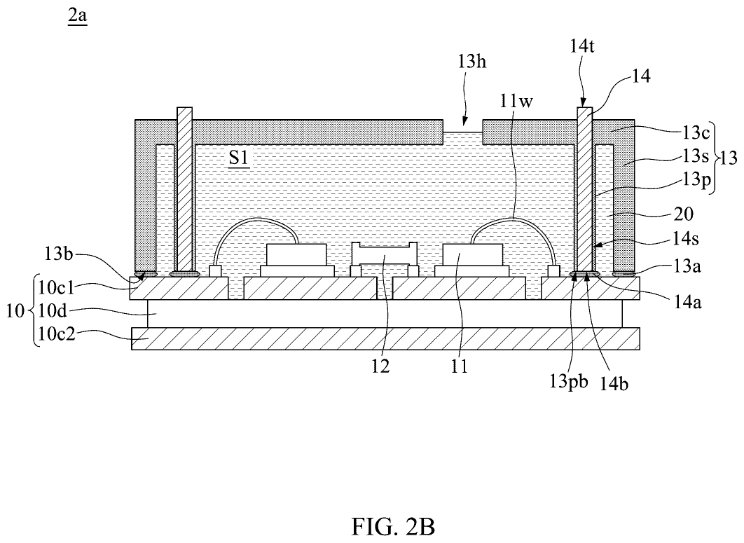

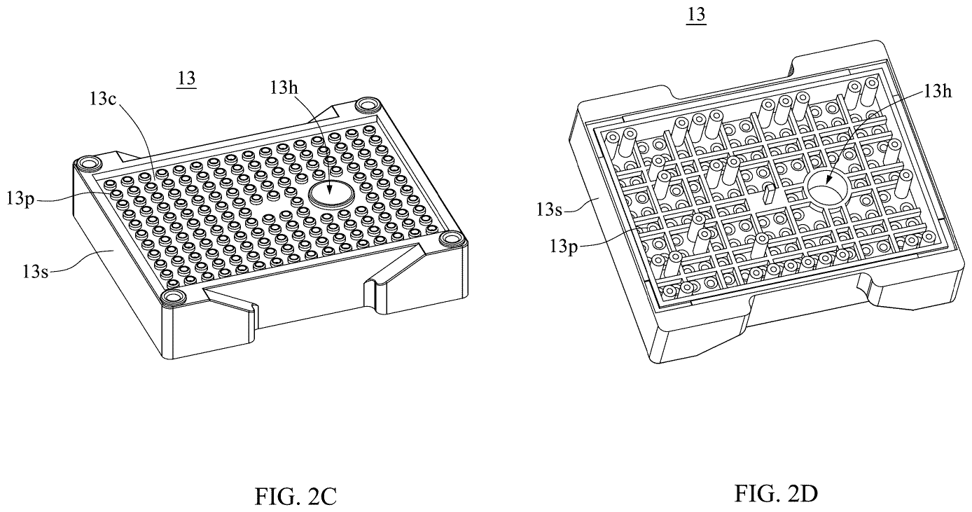

FIG. 2A illustrates a cross-sectional view of an electronic device 2a in accordance with some arrangements of the present disclosure. The electronic device 2a in FIG. 2A is similar to the electronic device 1a in FIG. 1A except for the differences described as follows.

The housing 13 may include a hole 13h. The hole 13h may penetrate through the cover 13c of the housing 13. In some arrangements, after the housing 13 is mounted on the carrier 10 (e.g., the operation in FIG. 4B), an encapsulant 20 may be disposed in the space S1 through the hole 13h. In some arrangements, the encapsulant 20 may fill the space S1. In some arrangements, the encapsulant 20 may be disposed in the hole 13h. In some arrangements, a top surface of the encapsulant 20 in the hole 13h may be recessed or curved. In some arrangements, a top surface of the encapsulant 20 in the hole 13h may be substantially coplanar with a top surface of the cover 13c.

In some arrangements, the encapsulant 20 may include an epoxy resin having fillers, a molding compound (e.g., an epoxy molding compound or another molding compound), a polyimide, a phenolic compound or material, a material with a silicone dispersed therein, or a combination thereof.

The encapsulant 20 may cover the electronic components 11 and 12. The encapsulant 20 may cover the conductive wire 11w. In some other arrangements, the encapsulant 20 may entirely surround or cover the holder 13p under the cover 13c. The encapsulant 20 may not contact the interconnection structures 14. The encapsulant 20 may be spaced apart from the interconnection structures 14. The encapsulant 20 may be separated from the interconnection structures 14 by the holder 13p.

In some other arrangements, the encapsulant 20 may partially surround or cover the holder 13p. For example, a lower portion of the holder 13p may be covered by the encapsulant 20 and an upper portion of the holder 13p may be uncovered. In some arrangements, the encapsulant 20 and the housing 13 may define a gap (such as an air gap).

In some arrangements, the encapsulant 20 may protect and fix the electronic components 11 and 12. The encapsulant 20 may enhance the durability and reliability of the components by shielding them from environmental factors such as moisture, dust, and mechanical stress. However, in a cost-reduction strategy, the electronic device 1a may be exclusive of the hole 13h and the encapsulant 20. The electronic components 11 and 12 may be uncovered. The conductive wire 11w may be uncovered. The holder 13p may be uncovered.

FIG. 2B illustrates a cross-sectional view of the electronic device 2a in accordance with some arrangements of the present disclosure. The electronic device 2a in FIG. 2B is similar to the electronic device 2a in FIG. 2A, except that the encapsulant 20 does not fill the hole 13h. For examples, the encapsulant 20 fills the hole 13h half full. For examples, the top surface of the encapsulant 20 and the sidewalls of the hole 13h define a recess portion.

FIG. 2C and FIG. 2D illustrate perspective views from different angles of the housing 13 in accordance with some arrangements of the present disclosure. In some arrangements, the housing 13 of the electronic device 2a in FIG. 2A may have perspective views as shown in FIG. 2C and FIG. 2D.

In some arrangements, the housing 13 may have a plurality of holders 13p. The interconnection structures 14 can be inserted or accommodated in one or more holders 13p based on specific requirements. For example, the interconnection structures 14 can be inserted or accommodated in one or more holders 13p, depending on the routing of the power paths.

The shapes, positions, relative locations, and quantities of the holders 13p are for illustrative purposes only and are not intended to limit the scope of the present disclosure.

In some arrangements, the hole 13h may be greater than an opening defined by the holders 13p. For example, the diameter of the hole 13h may be greater than the diameter of the opening defined by the holder 13p. In some arrangements, the hole 13h may be surrounded by the holders 13p. In some arrangements, the hole 13h may be located at the center of the cover 13c.

FIG. 3A, FIG. 3B, FIG. 3C, FIG. 3D, FIG. 4A, and FIG. 4B illustrate cross-sectional views in one or more stages of a method of manufacturing an electronic device in accordance with an arrangement of the present disclosure. At least some of these figures have been simplified to better understand the aspects of the present disclosure. In some arrangements, a part of the electronic device 1a may be manufactured through the operations described with respect to FIG. 3A, FIG. 3B, FIG. 3C, FIG. 3D, FIG. 4A, and FIG. 4B.

Referring to FIG. 3A, the housing 13 may be provided. The housing 13 may include a cover 13c, a sidewall 13s, and a holder 13p. The cover 13c may have the top surface 13t, which may be the highest surface of the housing 13. The sidewall 13s may have the bottom surface 13b. The holder 13p may have the bottom surface 13pb.

Referring to FIG. 3b, one or more housings 13 may be disposed over or on a plate 50.

Referring to FIG. 3C, the interconnection structures 14 may be disposed into the holders 13p while the housings 13 are supported by the plate 50. The interconnection structures 14 can be inserted or accommodated in one or more holders 13p based on specific requirements. For example, the interconnection structures 14 can be inserted or accommodated in one or more holders 13p, depending on the routing of the power paths. The interconnection structure 14 may be attached to the holder 13p through a mechanical or magnetic means.

Referring to FIG. 3D, after the interconnection structures 14 are inserted, the housing 13 may be removed from the plate 50. The end surface 14b of the interconnection structure 14, the bottom surface 13pb of the holder 13p, and the bottom surface 13b of the sidewall 13s may be substantially aligned.

Referring to FIG. 4A, the carrier 10 may be provided. The carrier 10 may include the surface 101 and the surface 102 opposite to the surface 101. The electronic component 11 may be disposed over or on the carrier 10 and electrically connected to the carrier 10 through the conductive wire 11w. The electrical contact 14a and the contact 13a may be disposed over or on the carrier 10. The electrical contact 14a and the contact 13a may be formed by a printing operation, a transferring operation, a dispensing operation, a plating operation, or any other suitable method.

Referring to FIG. 4B, the housing 13, along with the interconnection structure 14, may be disposed over the carrier 10 to cover the electronic component 11.

In some arrangements, a singulation may be performed to separate out individual electronic devices. The singulation may be performed, for example, by using a dicing saw, laser or other appropriate cutting techniques.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a carrier;
a housing disposed over the carrier and having a holder, wherein the holder extends continuously between a top surface and a bottom surface of the housing; and
an interconnection structure disposed in the holder and electrically connected with the carrier, wherein the housing and the interconnection structure are detachable from the carrier.

2. The electronic device of claim 1, wherein the housing includes a monolithic structure.

3. The electronic device of claim 1, wherein a diameter of the holder is greater than a diameter of the interconnection structure.

4. The electronic device of claim 1, wherein the interconnection structure protrudes beyond the top surface of the housing.

5. The electronic device of claim 1, wherein a bottom surface of the holder directly contacts the carrier.

6. The electronic device of claim 5, wherein the end surface of the interconnection structure directly contacts the carrier.

7. The electronic device of claim 1, further comprising:
an electronic component disposed over the carrier; and
a conductive wire connected between the electronic component and the carrier.

8. The electronic device of claim 7, wherein the conductive wire is uncovered.

9. The electronic device of claim 1, further comprising:
a connection disposed between the housing and the carrier.

10. A housing, comprising:
a cover;
a sidewall extending from the cover and having a first bottom surface;
a holder extending from the cover and having a second bottom surface; and
an interconnection structure secured in the holder, wherein the first bottom surface is substantially aligned with the second bottom surface.

11. The housing of claim 10, wherein the holder tapers away from the cover.

12. The housing of claim 10, further comprising:
an electrical contact connected between the interconnection structure and the carrier.

13. The housing of claim 12, wherein the electrical contact is disposed on a lateral surface of the interconnection structure.

14. The housing of claim 12, wherein the electrical contact is disposed between the holder and a lateral surface of the interconnection structure.

15. The housing of claim 10, wherein a gap between the holder and a lateral surface of the interconnection structure increased as it approached the cover.

16. The housing of claim 10, further comprising:
an encapsulant disposed in a hole of the cover.

17. The housing of claim 16, wherein the encapsulant is spaced apart from the interconnection structure.

18. A method for manufacturing an electronic device, comprising:
providing a housing including a holder;
disposing an interconnection structure in the holder; and
disposing the housing, along with the interconnection structure, over a carrier.

19. The method of claim 18, further comprising:
disposing the housing over a plate; and
removing the housing from the plate after the interconnection structure is disposed in the holder.

20. The method of claim 18, further comprising:
disposing an electronic component over the carrier; and
disposing the housing, along with the interconnection structure, over the carrier to cover the electronic component.
